(19) United States
(12) Patent Application Publication
(10) Pub. No.: US 2026/0038560 A1
(43) Pub. Date: Feb. 5, 2026

(54) APPARATUSES, SYSTEMS, AND METHODS FOR DYNAMIC SELF-REFRESH RATE IN VOLATILE MEMORY

(71) Applicant: Micron Technology, Inc., Boise, ID (US)

(72) Inventors: Wonjun Choi, Boise, ID (US); Hyun Yoo Lee, Boise, ID (US)

(73) Assignee: Micron Technology, Inc., Boise, ID (US)

(21) Appl. No.: 19/269,918

(22) Filed: Jul. 15, 2025

Related U.S. Application Data
(60) Provisional application No. 63/677,923, filed on Jul. 31, 2024.

(51) Int. Cl. G11C 11/406

(52) U.S. Cl. CPC G11C 11/40615

(57) ABSTRACT

Apparatuses, systems, and methods for dynamic self-refresh rate in volatile memory are disclosed. An example memory device determines a number of refresh operations performed between self-refresh exit and subsequent self-refresh entry, and the memory device determines a self-refresh rate based on the number of refresh operations. In some examples, the memory device selects a refresh rate curve from a plurality of refresh rate curves to determine the self-refresh rate. In some examples, the memory device selects a refresh rate curve for auto-refresh, which is applied to determine timing of self-refresh operations, when no refresh operations or few refresh operations were performed between the self-refresh exit and the subsequent self-refresh entry.

### CROSS-REFERENCE TO RELATED APPLICATIONS

This application claims the filing benefit of U.S. Provisional Application No. 63/677,923 filed Jul. 31, 2024. This application is incorporated by reference herein in its entirety and for all purposes.

### BACKGROUND

This disclosure relates generally to semiconductor devices, and more specifically to semiconductor memory devices. For example, disclosed embodiments may relate to volatile memory, such as dynamic random-access memory (DRAM). Information may be stored on individual memory cells of the memory device as a physical signal (e.g., a charge on a capacitive element). During a read operation the physical signal (e.g., the charge) may be coupled to a conductive element to cause a change in voltage. That change in voltage may be amplified and read out to input/output terminals of the device. A write operation may reverse the process, receiving a signal at the terminals and providing a voltage to the memory cell (e.g., to charge the capacitor).

Various types of memory devices exist, including random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), and others. Memory devices may be volatile or non-volatile. Non-volatile memory, e.g., flash memory, may maintain their stored logic state for extended periods of time even in the absence of an external power source. Volatile memory devices, e.g., DRAM, may lose their stored state when disconnected from an external power source.

In some cases, a memory device may perform refresh operations to read and restore the state of volatile memory cells to mitigate the potential loss of state information. For example, some volatile memory cells, such as DRAM cells, include a capacitor for storing the state of the memory cell, and such memory cells may need to be periodically refreshed.

### BRIEF DESCRIPTION OF THE DRAWINGS

FIG. 1 is a block diagram of a memory device according to an embodiment of the disclosure.

FIG. 2 is a display diagram illustrating refresh rate curves.

FIG. 3 is a timing diagram illustrating refresh operations performed by a memory device.

FIG. 4 is a timing diagram illustrating refresh operations performed by a memory device.

FIG. 5 is a timing diagram illustrating refresh operations performed by a memory device according to embodiments of the disclosure.

FIG. 6 is a block diagram illustrating a refresh control circuit of a memory device.

FIG. 7 is a timing diagram illustrating self-refresh control operations performed by a memory device.

### DETAILED DESCRIPTION

The following description of certain embodiments is merely illustrative in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory device is stored in memory cells of a memory array. The information is conveyed as voltages along various internal signal lines. For example, a first voltage may represent a logical high, while a second voltage may represent a logical low. Memory devices may perform refresh operations to prevent loss of the information. For example, memory cells may be refreshed by reading and restoring (e.g., restoring back to a first stored level) the state of the memory cells to mitigate the potential loss of state information due to, for example, charge leakage. For example, DRAM cells may include a capacitor for storing the state of the memory cell, and such memory cells may need to be refreshed to compensate for charge leakage from the capacitor over time. One or more refresh operations may be performed in response to receiving a refresh command from, for example, a controller or a host device, such as an auto-refresh command. Additionally, refresh operations may be performed in a self-refresh mode based on internal logic of a memory device in response to a self-refresh entry command.

Timing of refresh operations may be determined (e.g., by a refresh control circuit of a memory device) based on one or more refresh rate curves, which may specify different refresh rates based on a temperature of a memory device and/or other factors. Different refresh rate curves may be applied, for example, based on a type of refresh operation. In some examples, a first refresh rate curve may be applied to determine timing of self-refresh operations, and a second refresh rate curve may be applied to determine timing of auto-refresh operations. A refresh rate curve for self-refresh operations may specify less frequent refresh operations, as compared to refresh operations performed according to a refresh rate curve for auto-refresh operations.

Existing technologies may not allow flexible or dynamic refresh rates. For example, existing technologies may provide only a fixed refresh rate curve for self-refresh operations and a fixed refresh rate curve for auto-refresh operations. Technologies are needed that allow for dynamic adjustment of refresh rates (e.g., refresh rate curves) based on various factors, such as based on whether auto-refresh operations have been recently performed.

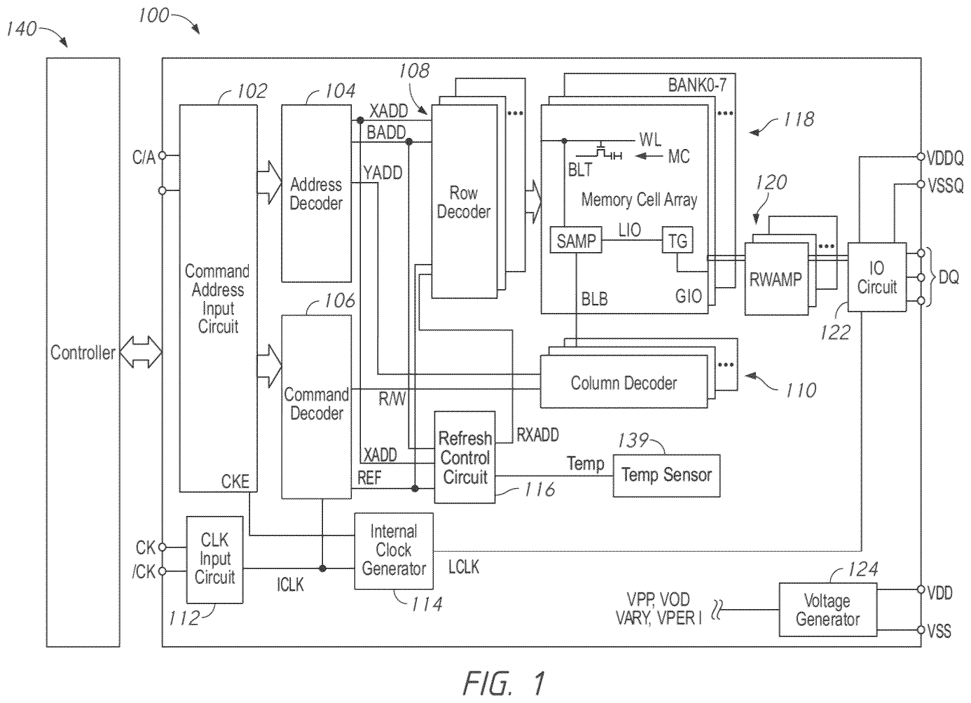

FIG. 1 is a block diagram of a memory device 100 according to an embodiment of the disclosure. The memory device 100 may be, for example, a DRAM device integrated on a single semiconductor chip. The memory device 100 is coupled to a controller 140, and the memory device 100 and the controller 140 may comprise a memory system.

The memory device 100 includes a memory array 118. The memory array 118 is shown as including a plurality of memory banks. In the embodiment of FIG. 1, the memory array 118 is shown as including eight memory banks BANK0-BANK7. More or fewer banks can be included in the memory array 118 of other embodiments. Each memory bank includes a plurality of word lines WL, a plurality of bit lines BLT and BLB, and a plurality of memory cells MC arranged at intersections of the plurality of word lines WL and the plurality of bit lines BLT (and BLB). The selection of the word line WL is performed by a row decoder 108 and the selection of the bit lines BLT, BLB is performed by a column decoder 110. In the embodiment of FIG. 1, the row decoder 108 includes a respective row decoder for each memory bank and the column decoder 110 includes a respective column decoder for each memory bank. The bit lines BLT, BLB are coupled to a respective sense amplifier (SAMP). Read data from the bit line BLT (or BLB) is amplified by the sense amplifier SAMP, and transferred to read/write amplifiers 120 over local data lines (LIO), transfer gate (TG), and global data lines (GIO). Conversely, write data outputted from the read/write amplifiers 120 is transferred to the sense amplifier SAMP over the complementary main data lines GIO, the transfer gate TG, and the complementary local data lines LIO, and written in the memory cell MC coupled to the bit line BLT (or BLB).

The memory device 100 may employ a plurality of external terminals that include command and address (C/A) terminals coupled to a command and address bus to receive commands and addresses from the controller 140, clock terminals to receive clocks CK and /CK from the controller 140, data terminals DQ coupled to a data bus to provide data to the controller 140, and power supply terminals to receive power supply potentials VDD, VSS, VDDQ, and VSSQ at respective conductive lines of the memory device 100.

The clock terminals are supplied with external clocks CK and/CK by the controller 140 that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. For example, the internal data clocks LCLK are provided to the input/output circuit 122 to time operation of circuits included in the input/output circuit 122, for example, to data receivers to time the receipt of write data. The input/output circuit 122 may include a number of interface connections, each of which may be couplable to one of the DQ pads (e.g., the solder pads which may act as external connections to the memory device 100).

The C/A terminals may be supplied with memory addresses by the controller 140. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The column decoder 110 may provide a column select signal, which may select one or more of the sense amplifiers SAMP. The address decoder 104 may also supply a decoded bank address BADD, which may indicate the bank of the memory array 118 containing the decoded row address XADD and column address YADD. The C/A terminals may be supplied with commands by the controller 140. Examples of commands include refresh commands (e.g., auto-refresh commands) including self-refresh commands (e.g., self-refresh entry commands, self-refresh exit commands), activate commands for activating pages of memory, access commands for accessing the memory, such as read commands for performing read operations and write commands for performing write operations, as well as other commands and operations. The activate and access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The memory device 100 may receive an access command from the controller 140 which is a read command. When activate and read commands are received, and a bank address, a row address, and a column address are timely supplied with the activate and read commands, read data is read from memory cells in the memory array 118 corresponding to the row address and column address. The read command is received by the command decoder 106, which provides internal commands so that read data from the memory array 118 is provided to the read/write amplifiers 120. The read data is provided along the data bus and output to outside from the data terminals DQ via the input/output circuit 122.

The memory device 100 may receive an access command from the controller 140 which is a write command. When activate and write commands are received, and a bank address, a row address, and a column address are timely supplied with the activate and write commands, write data supplied to the data terminals DQ is provided along the data bus and written to a memory cells in the memory array 118 corresponding to the row address and column address. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC.

The memory device 100 may receive commands causing it to carry out one or more refresh operations, such as a self-refresh entry command to cause performance of self-refresh operations as part of a self-refresh mode or an auto-refresh command to cause performance of auto-refresh operations. When an external signal indicates a refresh command, the command decoder 106 may decode the refresh command and provide the refresh signal REF (e.g., a self-refresh signal or an auto-refresh signal). The refresh signal REF is supplied to the refresh control circuit 116. The refresh control circuit 116 supplies a refresh row address RXADD to the row decoder 108, which may refresh one or more word lines WL indicated by the refresh row address RXADD.

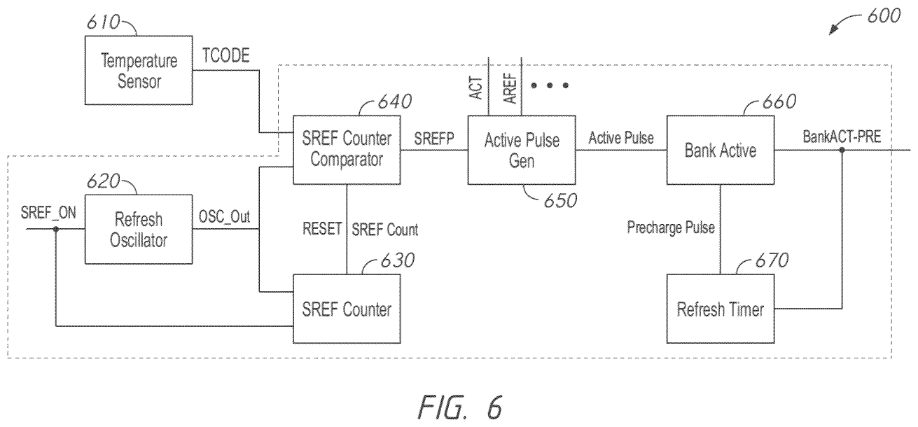

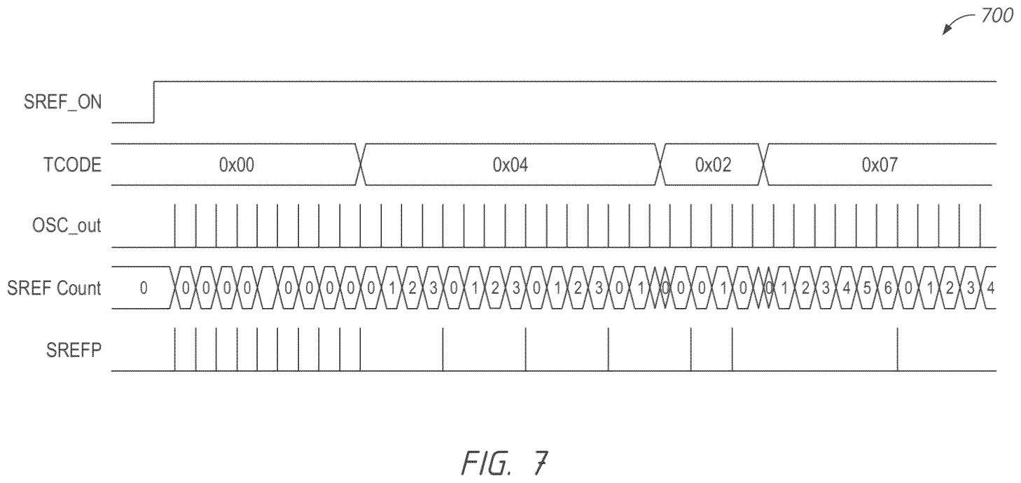

The refresh control circuit 116 may control timing of refresh operations, and may generate and provide the refresh address RXADD. In various embodiments, the refresh control circuit 116 causes performance of refresh operations based on a temperature signal TEMP provided by the temperature sensor 139. For example, the refresh control circuit may cause performance of refresh operations according to a self-refresh rate based on the temperature signal TEMP, as described with reference to FIGS. 6 and 7.

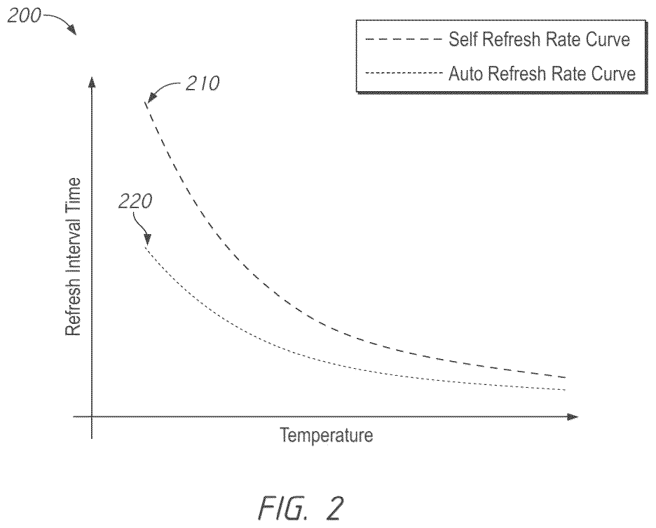

In various embodiments, the refresh control circuit 116 stores and uses one or more refresh rate curves specifying a refresh rate to be applied for a corresponding temperature (e.g., as illustrated with reference to FIG. 2). For example, a first refresh rate curve is applied for auto-refresh operations, and a second refresh rate curve is applied for self-refresh operations. In various embodiments, a self-refresh rate curve may specify less frequent refresh operations, as compared to an auto-refresh rate curve. In these and other embodiments, the refresh control circuit 116 may dynamically apply a refresh rate curve, for example, based on a number of refresh operations performed during a time period, such as a time period between self-refresh exit and self-refresh entry. When no refresh operations or few refresh operations have been performed during the time period, the refresh control circuit 116 may apply a refresh rate curve specifying more frequent self-refresh operations, such as an auto-refresh rate curve instead of a self-refresh rate curve. In some embodiments, the refresh rate curve specifying more frequent self-refresh operations is applied when no refresh operations have been performed during the time period. In some embodiments, the refresh rate curve specifying more frequent self-refresh operations is applied when few refresh operations (e.g., 2, 3, 5, 10) have been performed during the time period. In various embodiments, a default refresh rate curve (e.g., a self-refresh rate curve) is applied when the number of refresh operations during the time period exceeds a threshold, such as when at least one refresh operation has been performed during the time period. The number of refresh operations during the time period may be determined based on a number of refresh commands (e.g., auto-refresh commands) received during the time period, such as by storing a count value in the refresh control circuit 116, which is reset responsive to a self-refresh entry command or a self-refresh exit command. In some embodiments, a signal is provided at an active level or a flag is set to indicate that at least one refresh command has been received between refresh periods, and the signal or the flag is reset responsive to the self-refresh entry command or the self-refresh exit command.

In various embodiments, the refresh control circuit 116 determines a self-refresh rate (e.g., by selecting a refresh rate curve from a plurality of refresh rate curves) based on a number of refresh operations performed between a self-refresh exit command and a subsequent self-refresh entry command. As used herein, a self-refresh exit command can refer to a sequence of events that, when performed, cause the memory device 100 to exit a self-refresh mode. For example, self-refresh exit can be triggered when a chip select signal transitions from low to high and stays high for at least a threshold time (e.g., tCSH_SRExit), when a CA bus is driven high for at least a threshold time (e.g., tCASRX) prior to the chip select signal transitioning high, when three no-operation (NOP) commands are received, or combinations of these. The self-refresh exit command can also require that one or more timing delay criteria must be satisfied.

In an example implementation, the memory device 100 receives a self-refresh exit command from the controller 140 at a first time, and the memory device 100 exits the self-refresh mode responsive to the self-refresh exit command. At a second time after the first time, the memory device 100 receives a self-refresh entry command from the controller 140, and the memory device enters the self-refresh mode responsive to the self-refresh entry command. The refresh control circuit 116 determines a self-refresh rate for the self-refresh mode responsive to the self-refresh entry command at the second time based on a number of refresh operations performed between the first time and the second time. For example, the refresh control circuit 116 can maintain a count value to indicate a number of refresh commands (e.g., auto-refresh commands) received from the controller 140 between the first time and the second time. When the count value is below a threshold (e.g., less than 1, less than 2, less than 5), the refresh control circuit 116 may apply an increased refresh rate, and when the count value is above the threshold, the refresh control circuit 116 may apply a default refresh rate. In some examples, the default refresh rate is a refresh rate determined using a self-refresh rate curve, and the increased refresh rate is a refresh rate determined using an auto-refresh rate curve. In some examples, the refresh control circuit 116 selects a self-refresh rate curve from a plurality of self-refresh rate curves based on the count value, such that the refresh rate decreases as the count value increases.

Power supply terminals of the memory device 100 are supplied with power supply potentials VDD and VSS. The power supply potentials VDD and VSS are supplied to an internal voltage generator circuit 124. The internal voltage generator circuit 124 generates various internal potentials VPP, VOD, VARY, VPERI, and the like based on the power supply potentials VDD and VSS supplied to the power supply terminals. The power supply terminals are also supplied with power supply potential VDDQ. The power supply potentials VDDQ and VSS are supplied to the input/output circuit 122. The power supply potential VDDQ supplied to the power supply terminals may be the same potentials as the power supply potential VDD supplied to the power supply terminals. The power supply potential VDD supplied to the power supply terminals are used for the input/output circuit 122 so that power supply noise generated by the input/output circuit 122 does not propagate to the other circuit blocks.

FIG. 2 is a display diagram 200 illustrating refresh rate curves. In the illustrated example, the refresh rate curves include a self-refresh rate curve 210 and an auto-refresh rate curve 220. Each refresh rate curve specifies an interval time to be applied for refresh operations at different memory device temperatures, and each refresh rate curve specifies more frequent refresh operations as the device temperature increases (e.g., such that the interval time decreases exponentially). A refresh control circuit (e.g., 116 of FIG. 1) may store and use the illustrated refresh rate curves to determine timing of refresh operations (e.g., auto-refresh operations or self-refresh operations) performed by a memory device.

As discussed herein, existing technologies may use fixed refresh rate curves, such that the self-refresh rate curve 210 is applied to determine timing of self-refresh operations in a self-refresh mode and the auto-refresh rate curve 220 is applied to determine timing of auto-refresh operations responsive to auto-refresh commands. Such systems do not allow for flexible operation of memory devices, such that different refresh rates can be applied based on changed conditions.

By contrast, the disclosed technology may dynamically select and apply different refresh rate curves based on various factors, such as a number of refresh operations performed during a specified time period. In these and other embodiments, different refresh rate curves can be applied based on other factors, such as frequency and/or type of refresh operations performed during the specified time period. In various embodiments, the self-refresh rate curve 210 can be a default curve for performance of self-refresh operations, while the auto-refresh rate curve 220 can be applied for performance of self-refresh operations when the disclosed technology determines that few or no refresh operations have been performed before receiving a self-refresh entry command and after a previous self-refresh exit. Advantageously, applying the auto-refresh rate curve 220 during a self-refresh mode causes self-refresh operations to be performed with greater frequency when a number of refresh operations during the time period is below a threshold amount.

While two refresh rate curves are illustrated in the example of FIG. 2, more refresh rate curves can be used in other implementations. For example, a refresh rate curve can be selected from three or more refresh rate curves based on a number of refresh operations during the specified time period, such that self-refresh operations are performed with greater frequency when few or no refresh operations were performed during the specified time period and the frequency of self-refresh operations is progressively reduced when a greater number of refresh operations were performed during the specified time period. For example, a first refresh rate curve can be applied when no refresh operations are performed during the time period, a second refresh rate curve can be applied when few refresh operations (e.g., 1 to 5 refresh operations) are performed during the time period, and a third refresh rate curve can be applied when a greater number of refresh operations (e.g., 6 or more refresh operations) are performed during the time period, such that the first refresh rate curve specifies more frequent refreshes than the second refresh rate curve, and the second refresh rate curve specifies more frequent refreshes than the third refresh rate curve. Additionally, while a self-refresh rate curve 210 and an auto-refresh rate curve 220 are illustrated, different refresh rate curves can be used, such as a set of multiple self-refresh rate curves specifying different refresh rates. As described herein, the specified time period during which a number of refresh operations is counted may be a time period between self-refresh exit and a next self-refresh entry. Additionally or alternatively, the specified time period may be a different time period, such as a fixed time period (e.g., the preceding 0.5 seconds, 1 second, 5 seconds, 10 seconds, 30 seconds).

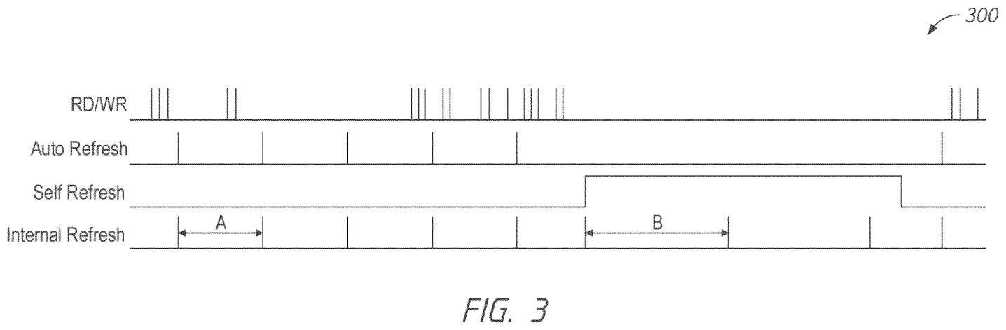

FIG. 3 is a timing diagram 300 illustrating refresh operations performed by a memory device. In the illustrated example, the memory device does not apply dynamic refresh rate curves, and the rate of refresh operations is determined using fixed refresh rate curves. The illustrated example assumes a constant temperature of the memory device.

The memory device performs access operations RD/WR at various times, which may be read operations or write operations. As described herein, the memory device performs refresh operations Internal Refresh to restore the state of volatile memory cells and mitigate the potential loss of state information. The refresh operations Internal Refresh include both self-refresh operations and auto-refresh operations.

In conventional memory systems, the memory device receives Auto Refresh commands from a controller, and the memory device performs refresh operations Internal Refresh responsive to the Auto Refresh commands, the refresh operations separated by interval A. The interval A for the refresh operations is determined using a fixed auto-refresh rate curve, such as the curve 220 of FIG. 2, based on a device temperature. Additionally, the memory device enters a Self Refresh mode responsive to a self-refresh entry command received from the controller. The Self Refresh mode is represented in FIG. 3 by an active (high) Self Refresh. The memory device performs refresh operations Internal Refresh according to internal logic of the memory device during the Self Refresh mode. The refresh operations are separated by interval B. The interval B for these refresh operations is determined using a fixed self-refresh rate curve, such as the curve 210 of FIG. 2, based on the device temperature. The interval B is greater than the interval A because the auto-refresh rate curve specifies more frequent refresh operations, as compared to the auto-refresh rate curve, for the same memory device temperature. During the time period illustrated in FIG. 3, nine refresh operations are performed.

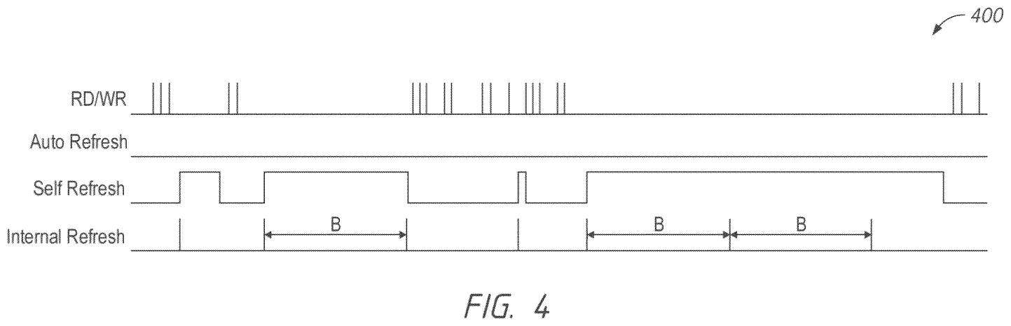

FIG. 4 is a timing diagram 400 illustrating refresh operations performed by a memory device. In the illustrated example, the memory device does not apply dynamic refresh rate curves, and the rate of refresh operations is determined using fixed refresh rate curves. The illustrated example assumes a constant temperature of the memory device. The memory device illustrated with reference to FIG. 4 may operate as described with reference to FIG. 3.

The memory device performs access operations RD/WR at various times, which may be read operations or write operations. As described herein, the memory device performs refresh operations Internal Refresh to restore the state of volatile memory cells and mitigate the potential loss of state information.

The memory device enters a Self Refresh mode responsive to a self-refresh entry command received from the controller. The Self Refresh mode is represented in FIG. 3 by an active (high) Self Refresh. The memory device performs refresh operations Internal Refresh according to internal logic of the memory device during the Self Refresh mode. The refresh operations are separated by interval B. The interval B for the refresh operations is determined using a fixed self-refresh rate curve, such as the curve 210 of FIG. 2.

In the illustrated example, no auto-refresh commands Auto Refresh are received. As a result, only self-refresh operations are performed, and only seven refresh operations are performed during the illustrated time period. The reduced frequency of refresh operations may increase the risk of data loss.

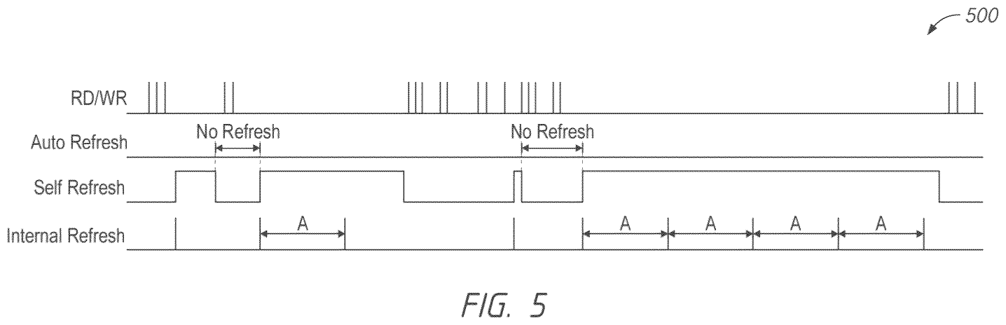

FIG. 5 is a timing diagram 500 illustrating refresh operations performed by a memory device according to embodiments of the disclosure. For example, the memory device may be the memory device 100 of FIG. 1. In the illustrated embodiment, the memory device applies dynamic refresh rate curves, such that the memory device may apply a refresh rate curve specifying more frequent self-refresh operations when no refresh operations or few refresh operations are performed between self-refresh exit and self-refresh entry. The illustrated example assumes a constant temperature of the memory device.

The memory device performs access operations RD/WR at various times, which may be read operations or write operations. As described herein, the memory device performs refresh operations Internal Refresh to restore the state of volatile memory cells and mitigate the potential loss of state information.

The memory device enters a Self Refresh mode responsive to a self-refresh entry command received from the controller, and the memory device performs refresh operations Internal Refresh according to internal logic of the memory device during the Self Refresh mode. In embodiments of the disclosure, a refresh control circuit of the memory device determines a number of refresh operations performed between self-refresh modes (i.e., between a self-refresh exit command and a next self-refresh entry command). When the number of refresh operations is below a threshold, the refresh control circuit may select a refresh rate curve specifying more frequent self-refresh operations, such as refresh operations separated by interval A instead of refresh operations separated by a greater interval (e.g., interval B, as illustrated in FIG. 4). For example, the embodiment of FIG. 5 may illustrate that the auto-refresh rate curve 220 of FIG. 2 is applied during the self-refresh mode when no refresh operations are performed between self-refresh modes instead of the self-refresh rate curve 210 of FIG. 2. As a result of applying dynamic refresh rate curves, a greater number of refresh operations are performed during the illustrated time period, as compared to the example of FIG. 4, even though no auto-refresh commands are received in the example of FIG. 5.

FIG. 6 is a block diagram illustrating a refresh control circuit 600 of a memory device. For example, the refresh control circuit 600 can be the refresh control circuit 116 of the memory device 100 of FIG. 1. The refresh control circuit 600 causes performance of refresh operations by the memory device, such as auto-refresh operations and self-refresh operations. For example, the memory device enters a self-refresh mode and performs self-refresh operations responsive to receiving a self-refresh activation signal SREF_ON (e.g., REF of FIG. 1). In an example implementation, the memory device receives a self-refresh command from a memory controller (e.g., 140 of FIG. 1), and the self-refresh command is decoded by a command decoder (e.g., 106 of FIG. 1), which generates the self-refresh activation signal SREF_ON and provides the self-refresh activation signal SREF_ON to the refresh control circuit 600.

A refresh oscillator 620 generates an oscillator signal OSC_out at an interval. For example, the refresh oscillator 620 may be activated by the self-refresh activation signal SREF_ON to generate the oscillator signal OSC_out as a pulse during a regular interval when the memory is in the self-refresh mode. The interval for the oscillator signal OSC_out may be, for example, 0.5 microseconds.

The refresh control circuit 600 further includes a self-refresh counter 630 that receives the oscillator signal OSC_out from the refresh oscillator and maintains a count of pulses of the oscillator signal OSC_out (e.g., since a most recent self-refresh operation or a change in the temperature signal TCODE). The self-refresh counter 630 generates a self-refresh count signal SREF count indicating the count. The count maintained by the self-refresh counter 630 may be reset responsive to performance of a refresh operation or an updated temperature signal TCODE provided by a temperature sensor 610.

The refresh control circuit 600 is coupled to the temperature sensor 610 (e.g., 139 of FIG. 1), which determines a current temperature of the memory device and generates the temperature signal TCODE based on the current temperature. The temperature signal TCODE is used to control timing of refresh operations. For example, the temperature signal TCODE may cause self-refresh operations to be performed with greater frequency as temperature of the memory device increases according to one or more refresh rate curves. In various implementations, a value of the temperature signal TCODE indicates a value of the self-refresh count signal SREF count that triggers a refresh operation according to a refresh rate curve, such that lower values of the temperature signal TCODE (e.g., 0x00) correspond to more frequent self-refresh operations and higher values (e.g., 0x07) correspond to less frequent self-refresh operations. Example temperature signals TCODE and corresponding temperature information are illustrated in Table 1 below.

TABLE 1

| | Temperature Signal | |
|---|---|---|
| Temperature | (TCODE) | Self-Refresh Interval |
| First Range | 0x07 | When SREF count = 7 (e.g., |
| (lower | | after 8 pulses of oscillator |
| temperature) | | signal OSC_out, if no |
| | | change in temperature |
| | | signal TCODE) |
| Second Range | 0x06 | When SREF count = 6 (e.g., |
| | | after 7 pulses of oscillator |
| | | signal OSC_out, if no |
| | | change in temperature |
| | | signal TCODE) |
| . . . | . . . | . . . |
| Third Range | 0x01 | When SREF count = 1 (e.g., |
| | | after two pulses of oscillator |
| | | signal OSC_out, if no |
| | | change in temperate signal |
| | | TCODE) |
| Fourth Range | 0x00 | When SREF count = 0 (after |
| (higher | | each pulse of oscillator |
| temperature) | | signal OSC_out) |

While first, second, third, and fourth temperature ranges are illustrated in Table 1, any number of temperature ranges and corresponding temperature signals TCODE can be used. In various implementations, refresh rates may be controlled according to refresh rate curves (e.g., 210 and 220 of FIG. 2), such that a refresh interval decreases exponentially or substantially exponentially as temperature of the memory device increases. Additionally, as described herein, different refresh rate curves can be applied based on various factors such as a number of refresh operations performed during a specified time period. For example, to implement different refresh rate curves, multipliers can be applied to outputs of the temperature sensor 610 and/or a table or other data structure can be used to store refresh rates corresponding to different refresh rate curves.

The refresh control circuit 600 includes a self-refresh counter comparator 640 that receives the temperature signal TCODE from the temperature sensor 610, the self-refresh count signal SREF count from the self-refresh counter 630, and the oscillator signal OSC_out from the refresh oscillator 620. The self-refresh counter comparator 640 compares the temperature signal TCODE to the self-refresh count signal SREF count and generates a self-refresh signal SREFP to cause performance of a self-refresh operation when the self-refresh count signal SREF count matches the value specified by the temperature signal TCODE. For example, when temperature signal TCODE=0x00, SREFP is generated when self-refresh count signal SREF count=0 (i.e., every 1 pulse of OSC_out); when temperature signal TCODE=0x01, SREFP is generated when self-refresh count signal SREF count=2 (e.g., every 2 pulses of OSC_out, if there is no change in TCODE); when temperature signal TCODE=0x02, SREFP is generated when self-refresh count signal SREF count=3 (e.g., every 3 pulses of OSC_out, if there is no change in TCODE); and so forth. The self-refresh counter comparator 640 generates a reset signal RESET and provides the reset signal RESET to the self-refresh counter 630 when the self-refresh signal SREFP is generated, and the reset signal RESET causes the self-refresh counter 630 to reset the count to zero. Additionally, the reset signal RESET is generated when there is a change in the temperature signal TCODE, which also causes the self-refresh counter 630 to reset the count to zero.

An active pulse generator 650 receives the self-refresh signal SREFP and also receives and processes various other active signals, such as activation command signals ACT, auto-refresh command signals AREF, self-refresh command signals SREF, and so forth. The active pulse generator 650 processes the self-refresh signal SREFP and/or the other active signals to generate a pulse signal Active Pulse to cause performance of a refresh operation.

A Bank Active component 660 receives the pulse signal Active Pulse and related precharge information, and the Bank Active component 660 generates a bank signal Bank ACT/Pre, which is provided to one or more banks in the memory device to cause performance of a refresh operation. Since the refresh operation may not be paired to a corresponding precharge command, a refresh timer 670 (e.g., a delay circuit) may generate a precharge signal Precharge Pulse to specify timing of performance of the refresh operation by the one or more banks in the memory device.

Example components of the refresh control circuit 600 are shown by way of illustration. More or fewer components may be included while maintaining a similar functionality, and various components may be combined.

FIG. 7 is a timing diagram 700 illustrating self-refresh control operations performed by a memory device. For example, the self-refresh operations may be performed by the memory device 100 of FIG. 1 using a refresh control circuit, such as the refresh control circuit 116 of FIG. 1 and/or the refresh control circuit 600 of FIG. 6.

The refresh control circuit receives a self-refresh activation signal SREF_ON, which causes the memory device to enter a self-refresh mode. The self-refresh activation signal SREF_ON may be received from a command decoder (e.g., 106 of FIG. 1) of the memory device responsive to a self-refresh command generated by a controller (e.g., 140 of FIG. 1).

During the self-refresh mode, a self-refresh counter comparator (e.g., 640 of FIG. 6) generates a self-refresh signal SREFP to cause performance of self-refresh operations at intervals based on a temperature signal CODE received from a temperature sensor (e.g., 610 of FIGS. 6 and/or 139 of FIG. 1) that detects a temperature of the memory device and a self-refresh count signal SREF count generated by a self-refresh counter (e.g., 630 of FIG. 6). The intervals for the self-refresh operations are determined using an oscillator signal OSC_out generated by a refresh oscillator (e.g., 620 of FIG. 6). The oscillator signal OSC_out may be generated at regular intervals throughout the self-refresh mode, such as every 0.5 microseconds.

When the temperature signal TCODE=0x00, indicating a high temperature of the memory device, the self-refresh counter comparator compares the self-refresh count signal SREF count to the value indicated by the temperature signal TCODE and generates the self-refresh signal SREFP when SREF count=0. In other words, the self-refresh signal SREFP is generated with every pulse of the oscillator signal OSC_out. The count indicated by the self-refresh count signal SREF count is reset after generation of each self-refresh signal SREFP. Accordingly, self-refresh operations are performed by the memory device at each of times t₁ through t₁₀.

At time t₁₀, a value of the temperature signal TCODE changes such that TCODE=0x03, indicating a lower temperature of the memory device, as compared to TCODE=0x00.

When the temperature signal TCODE=0x03, the self-refresh counter comparator compares the self-refresh count signal SREF count to the value indicated by the temperature signal TCODE and generates the self-refresh signal SREFP when SREF count=3. For example, the self-refresh signal SREFP is generated after four pulses of the oscillator signal OSC_out when there is no change in the temperature signal TCODE. The count indicated by the self-refresh count signal SREF count is reset after generation of each self-refresh signal SREFP. Accordingly, self-refresh operations are performed by the memory device at each of times t₁₁, t₁₂, and t₁₃.

At time t₁₄, a value of the temperature signal TCODE changes such that TCODE=0x01, indicating a higher temperature of the memory device, as compared to TCODE=0x03, but a lower temperature of the memory device, as compared to TCODE=0x00. Responsive to the changed temperature signal TCODE, the count indicated by the self-refresh count signal SREF count is reset.

When the temperature signal TCODE=0x01, the self-refresh counter comparator compares the self-refresh count signal SREF count to the value indicated by the temperature signal TCODE and generates the self-refresh signal SREFP when SREF count=1. For example, the self-refresh signal SREFP is generated after two pulses of the oscillator signal OSC_out when there is no change in the temperature signal TCODE. The count indicated by the self-refresh count signal SREF count is reset after generation of each self-refresh signal SREFP. Accordingly, self-refresh operations are performed by the memory device at each of times t₁₅ and t₁₆.

At time t₁₇, a value of the temperature signal TCODE changes such that TCODE=0x06, indicating a lower temperature of the memory device, as compared to TCODE=0x00, 0x01, or 0x03. Responsive to the changed temperature signal TCODE, the count indicated by the self-refresh count signal SREF count is reset.

When the temperature signal TCODE=0x06, the self-refresh counter comparator compares the self-refresh count signal SREF count to the value indicated by the temperature signal TCODE and generates the self-refresh signal SREFP when SREF count=6. For example, the self-refresh signal SREFP is generated after seven pulses of the oscillator signal OSC_out when there is no change in the temperature signal TCODE. The count indicated by the self-refresh count signal SREF count is reset after generation of each self-refresh signal SREFP. Accordingly, a self-refresh operation is performed by the memory device at time tis.

The memory device will continue performing self-refresh operations according to intervals based on the temperature signal TCODE until the memory device exits the self-refresh mode—that is, until the self-refresh activation signal SREF_ON is deactivated.

The timing diagram 700 may represent a memory device performing self-refresh operations at different temperatures according to one refresh rate curve. As described herein, the refresh rate can be determined based on a number of refresh operations performed during a specified time period (e.g., between self-refresh periods). Determining the refresh rate can include selecting a refresh rate curve from a set of refresh rate curves. Applying refresh rate curves may include, for example, using different sets of temperature signals TCODE, applying a multiplier to an output of a temperature sensor and/or the self-refresh count signal SREF count, determining refresh rates based on values stored in a table or other data structure (e.g., based on the temperature signal TCODE), or the like.

As used herein, an activation of a signal may refer to any portion of a signal waveform that a circuit responds to. For example, if a circuit responds to a rising edge, then a signal switching from a low level to a high level may be an activation. One example type of activation is a pulse, where a signal switches from a low level to a high level for a period of time, and then back to the low level. This may trigger circuits which respond to rising edges, falling edges, and/or signals being at a high logical level. One of skill in the art should understand that although embodiments may be described with respect to a particular type of activation used by a particular circuit (e.g., active high), other embodiments may use other types of activation (e.g., active low).

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory configured to:
receive a self-refresh exit command at a first time;
receive a self-refresh entry command at a second time after the first time, the self-refresh entry command for entry into a self-refresh mode;
determine a self-refresh rate based on a number of refresh operations performed between the first time and the second time; and
perform self-refresh operations according to the self-refresh rate during the self-refresh mode.

2. The apparatus of claim 1, wherein the self-refresh rate comprises:
a first self-refresh rate according to a first refresh rate curve when the number of refresh operations is below a threshold quantity; and
a second self-fresh rate according to a second refresh rate curve when the number of refresh operations is equal to or above the threshold quantity, wherein the first self-refresh rate is greater than the second self-refresh rate.

3. The apparatus of claim 2, wherein the first self-refresh rate is an auto-refresh rate.

4. The apparatus of claim 1, wherein the memory is configured to determine the self-refresh rate using a refresh rate curve.

5. The apparatus of claim 1, wherein the memory is configured to determine that the number of refresh operations is zero based on determining that no refresh commands were received between the first time and the second time, and wherein the self-refresh rate is a rate greater than when the number of refresh operations is greater than zero based on determining that one or more refresh commands were received between the first time and the second time.

6. The apparatus of claim 1, wherein the self-refresh rate is a default rate when an auto-refresh command is received between the first time and the second time.

7. The apparatus of claim 1, further comprising:
a controller configured to provide the self-refresh exit command and the self-refresh entry command.

8. The apparatus of claim 1, wherein the self-refresh exit command comprises a sequence including a chip select (CS) signal at a high logic level and a plurality of no-operation (NOP) commands.

9. The apparatus of claim 1, wherein the self-refresh rate is further based on a temperature of the memory.

10. The apparatus of claim 1, wherein the memory is configured to determine the self-refresh rate by selecting a refresh rate curve from a plurality of refresh rate curves.

11. A system comprising:
a command/address (CA) bus;
a memory controller configured to provide a self-refresh exit command via the CA bus at a first time and a self-refresh entry command via the CA bus at a second time after the first time; and
a memory configured to receive the self-refresh exit command and the self-refresh entry command via the CA bus and further configured to determine a self-refresh rate based on the determination of whether an auto-refresh command was received between the first time and the second time.

12. The system of claim 11, wherein the self-refresh rate is a first rate when the memory determines that the auto-refresh command was not received between the first time and the second time and wherein the self-refresh rate is a second rate when the memory determines that one or more auto-refresh commands were received between the first time and the second time, the first rate greater than the second rate.

13. The system of claim 12, wherein the first rate is an auto-refresh rate.

14. The system of claim 11, wherein the self-refresh rate is a default rate when the memory determines that the auto-refresh command was received between the first time and the second time.

15. The system of claim 11, wherein the self-refresh rate is determined using a refresh rate curve.

16. The system of claim 11, wherein the self-refresh exit command comprises a sequence including a chip select (CS) signal at a high logic level and a plurality of no-operation (NOP) commands.

17. The system of claim 11, wherein the self-refresh rate is further based on a temperature of the memory.

18. The system of claim 11, wherein the memory is configured to determine the self-refresh rate by selecting a refresh rate curve from a plurality of refresh rate curves.

19. A method comprising:
receiving, at a memory, a self-refresh exit command at a first time;
receiving, at the memory, a self-refresh entry command at a second time after the first time;
determining, by the memory, a self-refresh rate for a self-refresh mode based on a number of refresh operations performed between the first time and the second time; and
performing, by the memory, self-refresh operations during the self-refresh mode according to the self-refresh rate.

20. The method of claim 19, wherein the number of refresh operations performed between the first time and the second time is determined based on determining whether an auto-refresh command is received by the memory between the first time and the second time.

21. The method of claim 19, wherein the self-refresh rate is a first rate when the number of refresh operations is below a threshold quantity and wherein the self-refresh rate is a second rate when the number of refresh operations is equal to or greater than the threshold quantity, the first rate greater than the second rate.

22. The method of claim 21, wherein the first rate is an auto-refresh rate.

23. The method of claim 19, wherein the self-refresh rate is determined using a refresh rate curve.

24. A memory device comprising:
a memory array including a plurality of memory cells;
a temperature sensor configured to provide a temperature of the memory device; and
a refresh control circuit configured to store a plurality of refresh rate curves, select a refresh rate curve from the plurality of refresh rate curves based on a number of refresh operations performed during a time period, and determine a refresh rate for refreshing the plurality of memory cells in the memory array in a self-refresh mode based on the temperature of the memory device and the selected refresh rate curve.

25. The memory device of claim 24 further comprising:
a command decoder configured to decode a self-refresh entry command and provide a self-refresh signal at an active level to cause the memory device to enter the self-refresh mode.

26. The memory device of claim 24, wherein the time period is a time between self-refresh exit and subsequent self-refresh entry.

27. The memory device of claim 24, wherein the plurality of refresh rate curves includes a self-refresh rate curve and an auto-refresh rate curve.
